(19) United States
(12) Patent Application Publication
(10) Pub. No.: US 2009/0039441 A1
(43) Pub. Date: Feb. 12, 2009

(54) MOSFET WITH METAL GATE ELECTRODE

(76) Inventors: Hongfa Luna, Dresden (DE); Kisik Choi, Hopewell Junction, NY (US); Prashant Majhi, Austin, TX (US); Husam Alshareef, Austin, TX (US); Huang-Chun Wen, Dallas, TX (US); Rusty Harris, Austin, TX (US); Byoung Hun Lee, Austin, TX (US)

Correspondence Address: FULBRIGHT & JAWORSKI L.L.P., 600 CONGRESS AVE., SUITE 2400, AUSTIN, TX, 78701, US

(21) Appl. No.: 11/837,161

(22) Filed: Aug. 10, 2007

(51) Int. Cl. H01L 27/08; H01L 21/8238

(52) U.S. Cl. 257/383; 257/408; 438/199; 257/E27.046; 257/E21.632

(57) ABSTRACT

Devices comprising, and method for fabricating, a MOSFET with a metal gate electrode are disclosed. In one embodiment, the MOSFET includes a first doped region configured to receive current from a current source, a second doped region configured to drain current from the first doped region when an electric field is modified between the first doped region and the second doped region, and a gate electrode configured to modify the electric field. The gate electrode may include a high-k layer, a hafnium-based metal layer formed above the high-k layer, and a polysilicon layer formed above the hafnium-based metal layer. In a further embodiment, the gate electrode further comprises a titanium-based metal layer formed between the hafnium-based metal layer and the polysilicon layer.

### BACKGROUND OF THE INVENTION

1. Field of the Invention

The present invention relates generally to semiconductors and, more particularly, to a Metal-oxide Semiconductor Field-Effect Transistor (MOSFET) device with a metal gate electrode.

2. Description of Related Art

The gate electrode of a common MOSFET device typically includes a polycrystalline silicon (polysilicon) layer formed on an insulator, such as silicon oxide (SiO2). The SiO2 layer is commonly deposited or grown on a silicon semiconductor substrate, and a polysilicon layer is deposited on the SiO2 layer. In these common gate electrodes, the polysilicon acts as a conductor. This effect is achieved by doping the polysilicon with charge carriers. Generally, the preferred dopant is phosphorus.

In the field of semiconductor device fabrication, progress is commonly gauged by a reduction in the size of semiconductor components. Unfortunately, certain semiconductor structures and materials may become unsuitable as the size dramatically decreases. For example, SiO2 may not provide adequate insulation as the thickness decreases. Additionally, polysilicon may not be accurately tunable as the dimensions of the gate electrode structure decrease, because the number of available charge carriers may be physically limited by the size of the structure, and the total number of atoms comprising the structure.

These referenced shortcomings are not intended to be exhaustive, but rather are among many that tend to impair the effectiveness of previously known techniques concerning fabricating MOSFET devices. Those shortcomings mentioned here are sufficient to demonstrate that the methodologies appearing in the art have not been satisfactory and that a significant need exists for the techniques described and claimed in this disclosure.

### SUMMARY OF THE INVENTION

Devices comprising, and method for fabricating, a MOSFET with a metal gate electrode are disclosed. In one embodiment, the MOSFET includes a first doped region configured to receive current from a current source, a second doped region configured to drain current from the first doped region when an electric field is modified between the first doped region and the second doped region, and a gate electrode configured to modify the electric field. The gate electrode may include a hafnium(Hf)-based metal layer formed above the high-k dielectric layer, and a polysilicon layer formed on the Hf-based metal layer. In a further embodiment, the gate electrode further comprises a titanium(Ti)-based metal layer formed on the Hf-based metal layer, wherein the polysilicon layer is formed on the Ti-based metal layer.

In certain embodiments, the Ti-based metal layer includes a compound formed of titanium and nitrogen. In a further embodiment, the Ti-based metal layer may include a compound formed of titanium and silicon. The high-k layer may include hafnium oxide. The Hf-based metal layer may include hafnium and silicon. In a further embodiment, the Hf-based metal layer includes hafnium, silicon, and carbon.

The gate electrode may be configured to exhibit a work function of between 3.8 eV and 4.4 eV. Alternatively, the gate electrode may be configured to exhibit a work function of between 4.8 eV and 5.4 eV, particularly where the gate electrode includes the Ti-based metal layer. One of ordinary skill in the art of semiconductor design may recognize or have need of gate electrodes with work functions outside of these ranges. Accordingly, the gate electrode may be tuned to exhibit acceptable work function values by doping the polysilicon layer, or by adding additional metal layers to the gate electrode structure. The MOSFET may be further configured to maintain thermal stability at a temperature of up to one thousand degrees centigrade.

An Integrated Circuit (IC) device is also disclosed. In one described embodiment, the IC device includes a chip package configured to house an IC, multiple electrical interface pins configured to conduct electrical signals, and an IC that includes at least one MOSFET device disposed within the chip package. The MOSFET may include a first doped region configured to receive current from a current source, a second doped region configured to drain current from the first doped region when an electric field is modified between the first doped region and the second doped region, and a gate electrode configured to modify the electric field. The gate electrode may include a Hf-based metal layer formed above the high-k dielectric layer, and a polysilicon layer formed on the Hf-based metal layer. In a further embodiment, the gate electrode may include a Ti-based metal layer formed on the Hf-based metal layer, wherein the polysilicon layer is formed on the Ti-based metal layer.

In a further embodiment of the IC device, the MOSFET may include a complimentary MOSFET (CMOS) pair. The CMOS pair may include a p-type MOSFET (PMOS) portion and an n-type MOSFET (NMOS) portion. The PMOS portion and the NMOS portion may include a gate electrode respectively. In one embodiment, the gate electrode of the PMOS portion includes the Hf-based metal layer, the Ti-based metal layer, and the polysilicon layer. The gate electrode NMOS portion may include the h Hf-based metal layer, and the polysilicon layer.

A method of manufacturing the MOSFET device is also described. In one embodiment, the method includes providing a first doped region configured to receive current from a current source and providing a second doped region configured to drain current from the first doped region when an electric field is modified between the first doped region and the second doped region. Additionally, the method includes forming a gate electrode configured to modify the electric field. Forming the gate electrode may include forming a high-k layer, forming a Hf-based metal layer on the high-k layer, and forming a polysilicon layer on the Hf-based metal layer. Additionally, the method may include forming a Ti-based metal layer on the Hf-based metal layer, and forming the polysilicon layer on the Ti-based metal layer.

In a further embodiment, the method may include providing a p-type MOSFET (PMOS) portion of a complimentary MOSFET (CMOS) pair and providing an n-type MOSFET (NMOS) portion of a CMOS pair in proximity with the PMOS region. In such an embodiment, the method may include forming the high-k dielectric layer on the PMOS portion and the NMOS portion, forming the Hf-based metal layer on the high-k dielectric layer, forming the Ti-based metal layer on the Hf-based metal layer, forming a mask layer over the PMOS portion, removing the Ti-based metal layer from the NMOS portion, removing the mask layer from the PMOS portion, forming the polysilicon layer over the PMOS portion and the NMOS portion, defining a first gate electrode on the PMOS portion, and defining a second gate electrode on the NMOS portion. Additional embodiments may include performing a Post-Metallization Anneal (PMA) process after removing the Ti-based metal layer from the NMOS portion. Yet another embodiment may include performing a plasma treatment process after removing the Ti-based metal layer from the NMOS portion.

In a certain embodiment, forming the Hf-based metal layer further comprises depositing the Hf-based metal layer by a Chemical Vapor Deposition (CVD) process. The CVD process may include depositing a hafnium portion of the Hf-based metal layer with a Hf-containing precursor, and depositing a silicon portion of the Hf-based metal layer with a Si-containing precursor.

The term “coupled” is defined as connected, although not necessarily directly, and not necessarily mechanically. The terms “a” and “an” are defined as one or more unless this disclosure explicitly requires otherwise. The term “substantially,” “about,” and its variations are defined as being largely but not necessarily wholly what is specified as understood by one of ordinary skill in the art, and in one non-limiting embodiment, the substantially refers to ranges within 10%, preferably within 5%, more preferably within 1%, and most preferably within 0.5% of what is specified.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

Other features and associated advantages will become apparent with reference to the following detailed description of specific embodiments in connection with the accompanying drawings.

### BRIEF DESCRIPTION OF THE SEVERAL VIEWS OF THE DRAWING

The following drawings form part of the present specification and are included to further demonstrate certain aspects of the present invention. The invention may be better understood by reference to one or more of these drawings in combination with the detailed description of specific embodiments presented herein.

FIG. 1A is a schematic cross-section diagram illustrating one embodiment of a MOSFET device with a metal gate electrode;

FIG. 1B is a schematic cross-section diagram illustrating another embodiment of a MOSFET device with an alternative metal gate electrode;

FIG. 2 is a schematic cross-section diagram illustrating one embodiment of a CMOS device with metal gate electrodes;

FIG. 3 is a schematic top view and detailed view illustrating one embodiment of an IC device with a metal gate electrode;

FIG. 4 is a schematic flow chart diagram illustrating one embodiment of a method for making a MOSFET device with a metal gate electrode;

FIGS. 5A-5F are schematic cross-section diagrams illustrating one embodiment of manufacturing process stages corresponding to a method for making a CMOS device with metal gate electrodes.

### DETAILED DESCRIPTION OF THE INVENTION

The invention and the various features and advantageous details are explained more fully with reference to the nonlimiting embodiments that are illustrated in the accompanying drawings and detailed in the following description. Descriptions of well known starting materials, processing techniques, components, and equipment are omitted so as not to unnecessarily obscure the invention in detail. It should be understood, however, that the detailed description and the specific examples, while indicating embodiments of the invention, are given by way of illustration only and not by way of limitation. Various substitutions, modifications, additions, and/or rearrangements within the spirit and/or scope of the underlying inventive concept will become apparent to a person of ordinary skill in the art from this disclosure.

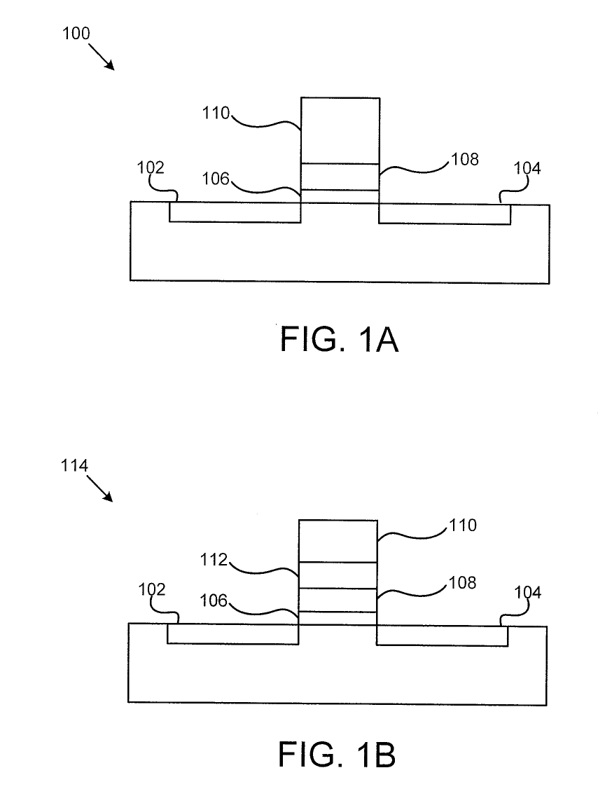

FIG. 1A illustrates one embodiment of a MOSFET 100. The MOSFET 100 may include a first doped region 102 and a second doped region 104. Additionally, the MOSFET 100 may include a gate electrode 210. As depicted in FIG. 1, the gate electrode 210 may include a Hf-based metal layer 108, and a polysilicon layer 110. The layer 106 is high-k dielectric film. The first doped region 102 may be configured to receive current from a current source. The second doped region 104 may be configured to drain current from the first doped region 102 when an electrical field is modified between the first doped region 102 and the second doped region 104. The gate electrode 210 may be configured to modify or substantially facilitate modification of the electric field between the first doped region 102 and the second doped region 104.

In certain embodiments, the first doped region 102 and the second doped region 104 may be separated. For example, the first doped region 102 and the second doped region 104 may be n-type doped regions, which are separated by a p-type doped region. Alternatively, the first doped region 102 and the second doped region 104 may be p-type doped regions separated by an n-type doped region. Various architectures, configurations, and doping schemes may be used to create the first doped region 102 and the second doped region 104. For example, in an NMOS transistor, the first doped region 102 and the second doped region 104 may be doped with negative electrons using a implantation process. In this example, the first doped region 102 and the second doped region 104 are considered n-type doped regions, because these regions contain excess negative electrons. In one embodiment, n-type doping is achieved by implanting arsenic, phosphorus, or the like using compounds of these elements. Alternatively, p-type doping may be achieved by implanting boron, or the like. One of ordinary skill in the art may recognize other potential dopants suitable for forming the first doped region 102 and the second doped region 104.

In a particular embodiment, the first doped region 102 is part of a source terminal of the MOSFET 100, and the second doped region 104 is part of a drain terminal of the MOSFET 100. In such an embodiment, a voltage supply may be connected to the first doped region 102. Under certain embodiments, the MOSFET 100 may exhibit an open circuit between the first doped region 102 and the second doped region 104 because of the separation, therefore, the second doped region 104 may be unable to drain current from the first doped region 102. The gate electrode 210 may be positioned between the first doped region 102 and the second doped region 104 in proximity with the separation. When a voltage is applied to the gate electrode 210, an electric field may be modified in the separation region. The electric field may induce electrons to move from the first doped region 102 biased at a lower potential, to the second doped region 104 biased at a higher potential. Thus, applying a voltage to the gate electrode 210 may trigger the second doped region 104 to drain electrons from the first doped region 102.

The term high-k means that the dielectric constant (k) is high relative to other typical dielectric materials. The high-k layer 106 may include a material with higher dielectric constant than typical gate dielectric materials, which enables the high-k layer 106 to be thicker than conventional dielectric layers while maintaining a similar level of capacitance. In one embodiment, high-k layer 106 may include hafnium-oxide (HfO2), hafnium silicate (HfSiOx), which has a higher dielectric constant than SiO2. In one embodiment, the HfO2 or HfSiOx layer may be deposited on the surface of a semiconductor substrate, or on another layer of a semiconductor device using an atomic layer deposition technique. One of ordinary skill in the art of semiconductor device fabrication may recognize other methods for depositing or growing a high-k layer 106 in light of this disclosure.

Certain semiconductor devices may include a polysilicon layer 110. Similarly, the MOSFET 100 of FIG. 1A may include a polysilicon layer 110. The polysilicon layer 110 may provide an electrical interface to other components or interconnects on an IC device 304, or may provide some level of physical and electrical isolation for the Hf-based metal layer 108. Additionally, the polysilicon layer 110 may contribute to the overall work function of the gate electrode 210. The term “work function” is commonly used in the art of semiconductor device design and manufacturing, and refers to the minimum energy needed to remove an electron from the surface of a metal. The work function of a metal is typically a constant characteristic of that metal, and is usually measured in electron Volts (eV). In such an embodiment, the work function of the overall gate electrode 210 may be finely tuned by adjusting the amount of dopant in the polysilicon layer. In one embodiment, an NMOS transistor may require the gate electrode 210 to exhibit a work function of between 3.8 eV and 4.4 eV, and a PMOS transistor may require the gate electrode 208 to exhibit a work function of between 4.8 eV and 5.4 eV. In alternative embodiments, the work function may fall outside of these ranges depending upon specific requirements of specific applications.

In a further embodiment, the gate electrode 210 may include a Hf-based metal layer 108. The Hf-based metal layer 108 may prevent a Fermi-pinning effect. The Fermi energy level is a quantity describing energy states of electrons within an atom, and is proportionate to the work function of the material. The Fermi energy level of a material may be adjusted by doping. This value is of interest in semiconductor device manufacturing, because it relates to the number of charge carriers that will be available to modify the electric field between the first doped region 102 and the second doped region 104. Fermi-pinning is a problem encountered when manufacturing very small gate electrode structures with high-k as dielectric layer and polysilicon as gate electrode. In that case, the Fermi level of polysilicon cannot be adequately tuned, regardless of the amount of dopant supplied to the polysilicon. The addition of the Hf-based metal layer 108 resolves the Fermi-pinning issue, at least in part, because the work function of Hf-based metal layer 108 can be as low as 4.0 eV.

In one embodiment, the Hf-based metal layer 108 may be deposited on the surface of the high-k layer 106 using a CVD process. Specifically, a Metal Organic CVD (MOCVD) process may be used. The MOCVD process refers to deposition of metals using CVD, where the precursor for the metal is an organic chemical structure, such as a carbon-based or nitrogen based chemical structure. For example, molecules containing hafnium atoms and carbon atoms may be mixed in a CVD chamber with molecules containing silicon atoms and nitrogen atoms. In certain embodiments some oxygen contamination may occur. Thus, in one embodiment, the resultant Hf-based metal layer 108 may include differing proportions of hafnium, silicon, carbon, oxygen, and nitrogen. If impurities are reduced, the Hf-based metal layer 108 may only include hafnium and silicon, or hafnium, silicon, and carbon, or the like.

In general, the presence of impurities such as carbon, oxygen, and nitrogen in the CVD chamber is undesirable. Therefore, most CVD processes include measures to reduce the level of these contaminants. However, the inventors of the various embodiments of the present invention have discovered that, with respect to the Hf-based metal layer 108 described herein, the addition of these contaminants, and particularly the carbon contaminant provides thermal stability for the gate electrode 208, 210 at a temperature of up to one thousand (1000) degrees centigrade. Therefore, the use of a carbon based precursor in the MOCVD process provides a surprising level of thermal stability for the resulting Hf-based metal layer 108 through purposeful and calculated carbon contamination of the Hf-based layer.

FIG. 1B illustrates an alternative embodiment of a MOSFET 114. In the depicted embodiment, the structure may be substantially the same as that of the MOSFET 100 depicted in FIG. 1A. However, the gate electrode of FIG. 1B includes an additional metal layer 112. In one embodiment, the additional metal layer 112 includes a Ti-based metal layer 112. The addition of the Ti-based metal layer 112 may, among other things, modify the overall work function of the gate electrode 208. For example, where the work function of the gate electrode 210 which only includes the Hf-based metal layer may be between 3.8 eV and 4.4 eV, the work function of the gate electrode 208 that includes both the Hf-based metal layer 108 and the Ti-based metal layer 112 may be between 4.8 eV and 5.4 eV. The difference may be attributed to diffusion between the two metal layers, where the Ti-based metal layer 112 may have a higher work function than the Hf-based metal layer 108. Thus, the resulting total work function is greater than the work function of the Hf-based metal layer 108 alone. In one embodiment, the Ti-based metal layer 112 may include a compound formed of titanium and silicon, or nitrogen, or both. The Ti-based metal layer 112 may be formed using a ALD process, CVD process or a Physical Vapor Deposition (PVD) process. For simplification, the MOSFET devices 100, 114 described in FIGS. 1A and 1B respectively are referred to collectively as the “MOSFET 100” from this point forward.

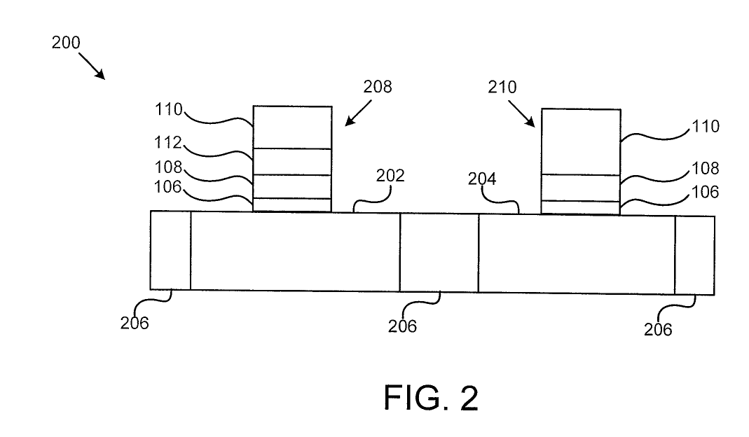

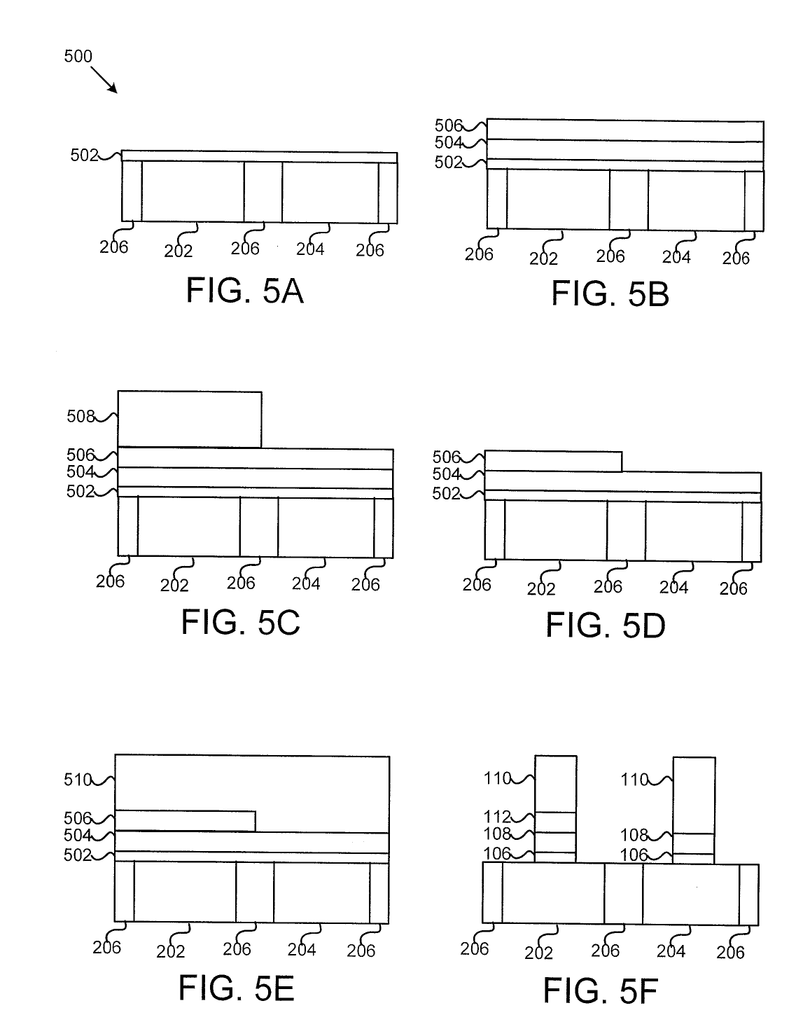

FIG. 2 illustrates a further embodiment of a MOSFETs 100 described above. In this embodiment, a PMOS transistor portion 202 and an NMOS transistor portion 204 are coupled to form a CMOS transistor 200. The PMOS portion 202 and the NMOS portion 204 may be separated by one or more isolation regions 206. The isolation regions may include undoped silicon, polysilicon, dielectric materials or the like. In one embodiment, the PMOS portion 202 is substantially as described with relation to the MOSFET 214 of FIG. 1B. The NMOS portion 204 may include structures substantially similar to those described with relation to the MOSFET 100 of FIG. 1A. In such an embodiment, the PMOS region 202 may include a gate electrode 208. The PMOS gate electrode 208 may include an Hf-based metal layer 108, a Ti-based metal layer 112, and a polysilicon layer 110. In a further embodiment, the NMOS portion 204 may also include a gate electrode 210. The NMOS gate electrode 210 may include the Hf-based metal layer 108, and the polysilicon layer 110. In one embodiment, the gate electrode 208 for the PMOS portion 202 has a work function of between 4.8 eV and 5.4 eV, whereas the gate electrode 210 of the NMOS portion 204 has a work function of between 3.8 eV and 4.4 eV. Methods of making the CMOS transistor 200 are discussed further with respect to FIGS. 5A-5F below.

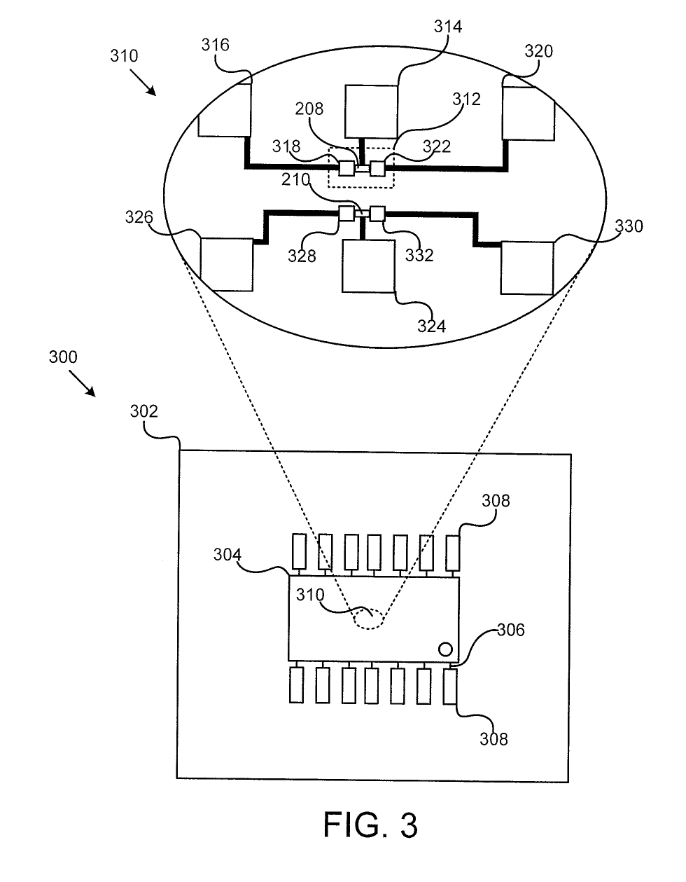

FIG. 3 illustrates one embodiment of an IC device 300. In the depicted embodiment, the IC device may include an integrated chip component. The chip may include a chip package 304, and IC 310, and one or more electrical interface pins 308. For simplicity, these components may be referred to collectively as a “chip 304.” A portion of the IC 310 is described in further detail. In the detailed illustration, the IC 310 may include, among other things, one or more MOSFETs 100, 200. Various embodiments of the MOSFETs 100, 200 are described above. In this depicted embodiment, the IC 310 includes a PMOS transistor 114, and an NMOS transistor 100. In a further embodiment, these transistors 100 may be coupled to form a CMOS transistor pair 200.

The depicted PMOS transistor includes an n-type doped well 312. The first doped region 318 and the second doped region 322 may be p-typed doped. Therefore, the first doped region 318 and the second doped region 322 may be separated by an n-type doped region of the n-type well 312. In addition, the PMOS may include a gate electrode 208. The gate electrode 208 may include an Hf-based metal layer 108, a Ti-based metal layer 112, and a polysilicon layer 110. The first doped region 318 may be coupled to a source terminal or connection pad 316, the second doped region 322 may be coupled to a drain pad 320, and the gate electrode 208 may be connected to a gate pad 314.

Similarly, the NMOS transistor includes a first doped region 328, a second doped region 332, and a gate electrode 210. In one embodiment, the gate electrode 210 includes an Hf-based metal layer 108, and a polysilicon layer 110. The first doped region 328 may be coupled to a source pad 326, the second doped region 332 may be connected to a drain pad 330, and the gate electrode 210 may be connected to a gate pad 324.

In various other embodiments of the IC, the transistors may be coupled directly to other transistors, or IC components through metal layers or connections. Indeed, certain ICs may include multiple layers, wherein the transistors are connected through vias between the layers. The IC may comprise a memory device, a processing device, a Radio Frequency (RF) device, a control device, a Field Programmable Gate Array (FPGA), an Application Specific Integrated Circuit (ASIC), a Programmable Logic Device (PLD), or the like. Although several embodiments of a chip 304 have been listed for illustrative purposes, one of ordinary skill in the art will recognize that this is not an exhaustive list of possible IC devices 300.

In a further embodiment, the chip 304 may be coupled to a circuit card 302 using one or more contact pads 308 or other means for electrical communication. For example, a computer motherboard may include a plurality of chips 304 containing ICs 310. In one embodiment, the chip 304 may be a computer processor, or the like. Alternatively, certain wireless communication devices may include wireless cards 302 which may include one or more chips 304 in a set of communication chips 304. Such chips 304 may include ICs 310 that contain one or more MOSFETs 100 as described above.

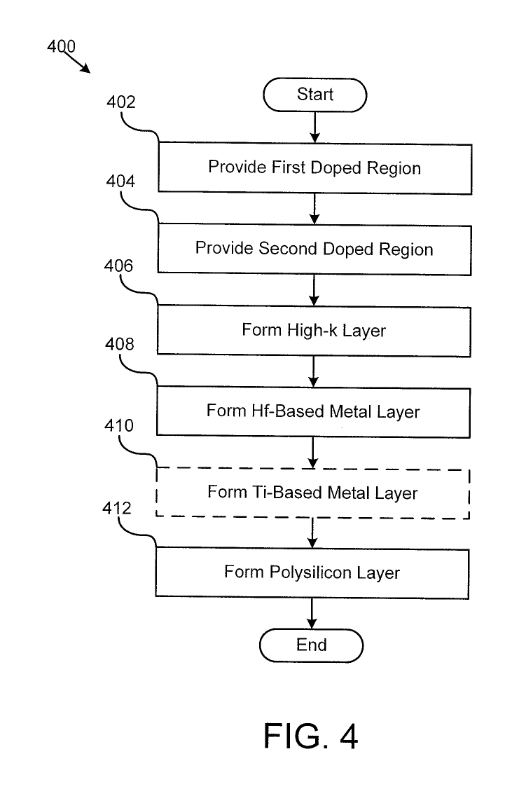

FIG. 4 illustrates one embodiment of a method 400 for making a MOSFET 100, 200. In one embodiment, the method 400 includes providing 402 a first doped region 102, and providing 404 a second doped region 104. Additionally, the method 400 may include forming 406 a high-k layer 106. In a further embodiment, the method 400 includes forming 408 an Hf-based metal layer 108 on the high-k layer 106. In certain embodiments, the method 400 may additionally include forming a Ti-based metal layer 112 on the Hf-based metal layer 108. In such an embodiment, a polysilicon layer 110 is formed 412 on the Ti-based metal layer 112. Alternatively, if the Ti-based metal layer 112 is not formed 410, the polysilicon layer 110 may be formed 412 on the Hf-based metal layer 108.

In one example of the method 400 described above, the high-k layer 106 may then be formed 406 over the surface of the silicon substrate, including over the area of the first doped region 102, and the second doped region 104. In one embodiment, the high-k layer 106 may be grown or deposited using an atomic layer deposition technique, or the like.

The Hf-based metal layer 108 may then be formed 408 using an MOCVD process. For example, a compound comprising hafnium and a carbon based precursor may be injected into a CVD chamber. Additionally, a second compound comprising silicon and a nitrogen based precursor may be injected and mixed with the hafnium compound in the CVD chamber. In such an embodiment, the Hf-based metal layer 108 may form 408 on the surface of the high-k layer 106. An Hf-based metal layer 108 formed 408 by such a process may include hafnium and silicon, as well as trace contaminants of carbon, nitrogen, and oxygen. In an alternative embodiment, the hafnium and/or silicon may be deposited using a PVD process.

In certain embodiments, the method 400 may additionally include forming 410 a Ti-based metal layer 112 on the surface of the Hf-based metal layer 108. The Ti-based metal layer 112 may similarly be formed 410 using either a PVD or a CVD process. In a certain embodiment, the Ti-based metal layer 112 may be formed 410 using a CVD process, where the titanium is mixed with silicon and nitrogen. Alternatively, the titanium may be mixed only with nitrogen to form 410 a titanium nitride (TiN) layer.

The polysilicon layer 110 may be formed 412 by placing the structure in an environment at or about six hundred (600) degrees centigrade and in the presence of silane. In such an environment, the polysilicon layer 110 may form 412 on the surface of the Hf-based layer 108, or on the surface of the Ti-based layer 112.

Then, the first doped region 102 and the second doped region 104 may be formed 402, 404 by forming a mask layer on a silicon substrate. The mask layer may be etched to expose the surface of the silicon substrate in the areas designated for the first doped region 102 and the second doped region 104. These unmasked areas may be doped using one of several doping methods, including ion implantation, diffusion, and the like.

FIGS. 5A-5F collectively illustrate phases of a semiconductor fabrication process 500 for fabricating gate electrodes 208, 210 on a CMOS transistor 200. In one embodiment, the final product of this process may be substantially similar to the CMOS transistor 200 described in FIG. 2 above. Referring now to FIG. 5A, as described in FIG. 2, a PMOS region 202 and an NMOS region 204 may be provided. Specifically, the PMOS region 202 and the NMOS region 204 may include a first doped region 102 and a second doped region 104, wherein the doping is suited specifically for the PMOS 202 region and NMOS region 204 respectively. The PMOS region 202 and the NMOS region 204 may be separated by isolation regions 206. In one embodiment, these regions may be formed in or on a substrate, such as silicon, silicon-germanium, gallium-arsenide, or the like.

A high-k layer 502 may be formed across the surface of the of the PMOS region 202 and the NMOS region 204. In a further embodiment, illustrated in FIG. 5B, an Hf-based layer 504 and a Ti-based layer 506 may be formed across the surface of the high-k layer 502. In a specific embodiment, both layers 504, 506 may be formed across the entire surface of the high-k layer 502. Next, an isolation mask layer 508 may be formed over the PMOS portion 202 as illustrated in FIG. 5C. The isolation mask layer 508 may include a photoresist (PR) compound. The PR compound may be baked to form a soft mask or a hard mask, depending on the desired lithography process.

As illustrated in FIG. 5D, the Ti-based metal layer 506 may be etched from the surface of the Hf-based layer 504 in the unmasked area. The Ti-based metal layer 506 may be removed using various etch processes, including wet chemical etch, Dry Reactive Ion Etch (RIE), or the like. The isolation mask layer 508 may then be removed, and a post metallization anneal process may be performed. For example, the structure may be baked at a temperature of six hundred (600) to one thousand (1000) degrees centigrade. The post metallization anneal process may allow the metal layers to cure, or may slightly melt the metal layers 108, 112 allowing certain unconformities produced during the etch process to be smoothed. In an alternative embodiment the structure may be treated with a plasma. For example, an N2 plasma treatment may be used on the structure to produce the anneal effect. These metal treatment processes may slightly alter the work function of the overall structure, by inducing some diffusion between the layers.

A polysilicon layer 510 layer may be deposited over both the Ti-based metal layer 506 and the exposed Hf-based metal layer 504 as illustrated in FIG. 5E. Another mask layer (not illustrated) may then be deposited over the polysilicon layer 510, and the gate electrodes 208, 210 may be defined using an etch process, such as DRIE, or the like. In such an embodiment, the resultant gate electrodes 208, 210 may include the high-k layer 106, the Hf-based metal layer 108, the Ti-based metal layer 112, and the polysilicon layer 110 substantially as described in FIG. 2.

In such a process 500, both the PMOS gate electrode 208, and the NMOS gate electrode 210 may be formed in a single process 500. In the described embodiment, the high-k layer 106 is not exposed to damaging etch processes, because the high-k layer 106 is protected by the Hf-based metal layer during the entire process 500.

All of the methods disclosed and claimed herein can be executed without undue experimentation in light of the present disclosure. While the methods of this disclosure may have been described in terms of preferred embodiments, it will be apparent to those of ordinary skill in the art that variations may be applied to the methods and in the steps or in the sequence of steps of the method described herein without departing from the concept, spirit and scope of the disclosure. All such similar substitutes and modifications apparent to those skilled in the art are deemed to be within the spirit, scope, and concept of the disclosure as defined by the appended claims.

1. A Metal-oxide Semiconductor Field-Effect Transistor (MOSFET), comprising:
a first doped region configured to receive current from a current source;
a second doped region configured to drain current from the first doped region when an electric field is modified between the first doped region and the second doped region; and
a gate electrode configured to modify the electric field, the gate electrode comprising:
a high-k layer;
a hafnium-based metal layer formed above the high-k layer; and
a polysilicon layer formed above the hafnium-based metal layer.

2. The MOSFET of claim 1, wherein the gate electrode further comprises a titanium-based metal layer formed between the hafnium-based metal layer and the polysilicon layer.

3. The MOSFET of claim 2, wherein the titanium-based metal layer comprises titanium and nitrogen.

4. The MOSFET of claim 2, wherein the titanium-based metal layer comprises titanium and silicon.

5. The MOSFET of claim 1, wherein the high-k layer further comprises hafnium oxide.

6. The MOSFET of claim 1, wherein the hafnium-based metal layer comprises hafnium and silicon.

7. The MOSFET of claim 6, wherein the hafnium-based metal layer comprises hafnium, silicon, and carbon.

8. The MOSFET of claim 1, wherein the gate electrode is configured to exhibit a work function of between 3.8 eV and 4.4 eV.

9. The MOSFET of claim 2, wherein the gate electrode is configured to exhibit a work function of between 4.8 eV and 5.4 eV.

10. The MOSFET of claim 1, further configured to maintain thermal stability at a temperature of up to one thousand degrees centigrade.

11. An Integrated Circuit (IC) device, comprising:
a chip package configured to house an IC;
a plurality of electrical interface pins coupled to the chip package and in communication with the IC, the electrical interface pins configured to conduct electrical signals; and
an IC comprising at least one Metal-Organic Semiconductor Field-Effect Transistor (MOSFET) disposed within the chip package, the MOSFET comprising:
a first doped region configured to receive current from a current source;
a second doped region configured to drain current from the first doped region when an electric field is modified between the first doped region and the second doped region; and
a gate electrode configured to modify the electric field, the gate electrode comprising:
a high-k layer;
a hafnium-based metal layer formed above the high-k layer; and
a polysilicon layer formed above the hafnium-based metal layer.

12. The IC device of claim 11, wherein the gate electrode further comprises a titanium-based metal layer formed between the hafnium-based metal layer and the polysilicon layer.

13. The IC device of claim 12, wherein the titanium-based metal layer comprises titanium and nitrogen.

14. The IC device of claim 12, wherein the titanium-based metal layer comprises titanium and silicon.

15. The IC device of claim 11, wherein the hafnium-based metal layer comprises hafnium and silicon.

16. The IC device of claim 11, wherein the hafnium-based metal layer comprises hafnium, silicon, and carbon.

17. The IC device of claim 12, wherein the MOSFET further comprises a complimentary MOSFET (CMOS) pair comprising a p-type MOSFET (PMOS) portion and an n-type MOSFET (NMOS) portion, the PMOS portion and the NMOS portion comprising a gate electrode respectively, wherein the gate electrode of the PMOS portion comprises the high-k layer, the hafnium-based metal layer, the titanium-based metal layer, and the polysilicon layer, and wherein the gate electrode NMOS portion comprises the high-k layer, the hafnium-based metal layer, and the polysilicon layer.

18. A method comprising:
providing a first doped region configured to receive current from a current source;
providing a second doped region configured to drain current from the first doped region when an electric field is modified between the first doped region and the second doped region; and
forming a gate electrode configured to modify the electric field, wherein forming the gate electrode comprises:
forming a high-k layer;
forming a hafnium-based metal layer on the high-k layer; and
forming a polysilicon layer on the hafnium-based metal layer.

19. The method of claim 18, wherein forming the gate electrode further comprises forming a titanium-based metal layer on the hafnium-based metal layer, and forming the polysilicon layer on the titanium-based metal layer.

20. The method of claim 19, further comprising:
providing a p-type MOSFET (PMOS) portion of a complimentary MOSFET (CMOS) pair;
providing an n-type MOSFET (NMOS) portion of a CMOS pair in proximity with the PMOS region;
forming the high-k layer on the PMOS portion and the NMOS portion;
forming the hafnium-based metal layer on the high-k layer;
forming the titanium-based metal layer on the hafnium-based metal layer;
forming a mask layer over the PMOS portion;
removing the titanium-based metal layer from the NMOS portion;
removing the mask layer from the PMOS portion;
forming the polysilicon layer over the PMOS portion and the NMOS portion;
defining a first gate electrode on the PMOS portion; and
defining a second gate electrode on the NMOS portion.

21. The method of claim 20, further comprising performing a post metallization anneal (PMA) process after removing the titanium-based metal layer from the PMOS portion.

22. The method of claim 20, further comprising performing a plasma treatment process after removing the titanium-based metal layer from the PMOS portion.

23. The method of claim 18, wherein forming the hafnium-based metal layer further comprises depositing the hafnium-based metal layer by a Chemical Vapor Deposition (CVD) process.

24. The method of claim 23, wherein the CVD process further comprises:
depositing a hafnium portion of the hafnium-based metal layer with a carbon-containing precursor; and
depositing a silicon portion of the hafnium-based metal layer with a nitrogen-containing precursor.
